(19) United States
(12) Patent Application Publication
(10) Pub. No.: US 2020/0381570 A1
(43) Pub. Date: Dec. 3, 2020

(54) Eco-Friendly CuGaS2/ZnS Nanocrystals working as Efficient UV-Harvesting Down-Converter for Photovoltaics

(71) Applicants: Mohammed Jalalah, Najran (SA); Mohammad Sultan Al-Assiri, Najran (SA); Jea-Gun Park, Seoul (KR)

(72) Inventors: Mohammed Jalalah, Najran (SA); Mohammad Sultan Al-Assiri, Najran (SA); Jea-Gun Park, Seoul (KR)

(21) Appl. No.: 16/870,989

(22) Filed: May 10, 2020

Related U.S. Application Data
(60) Provisional application No. 62/854,419, filed on May 30, 2019.

(51) Int. Cl. H01L 31/055; H01L 31/0224; C09K 11/62

(52) U.S. Cl. CPC H01L 31/055; B82Y 20/00; C09K 11/623; H01L 31/022425

(57) ABSTRACT

Provided here nontoxic CuGaS₂/ZnS core/shell nanocrystals with free-self-reabsorption losses and large Stokes shift synthesized on an industrially gram-scale. The nanocrystals exhibited a typical energy-down-shift that absorbs only ultraviolet light and emits the whole range of visible light with a high photoluminescence-quantum yield. The straightforward application of these energy-down-shift nanocrystals on the front surface of a monocrystalline p-type silicon solar cell significantly enhanced the short-circuit current density and power conversion efficiency. The significant improvement in the external quantum efficiency and that decreasing in the surface reflectance in the ultraviolet region clearly manifest the photovoltaic enhancement. Such promising results together with the simple (one-pot core/shell synthesis), cost-effective, and scalable preparation methods might encourage the manufacturers of solar cells and other optoelectronic applications to apply these energy-down-shift nanocrystals to different broader eco-friendly applications.

### BACKGROUND OF THE INVENTION

Enhancing energy conversion efficiency is one of the most important issues in today's global solar photovoltaic (PV) technology in which great effort and research have been made toward achieving higher conversion efficiency at lower production cost. ^{[1]} However, the majority of PV cell types, such as Si,^{[2]} CuInₓGr₁₋ₓSe_{y}S_{1-y} (CIGS),^{[3]} Cu₂ZnSnS₄₋ₓSeₓ (CZTS),^{[4]} GaAs,^{[5]} CdTe,^{[6]} dye-sensitized (DSSC),^{[7]} perovskite,^{[8]} and organic solar cells^{[9]} still suffer from low external quantum efficiency (EQE) in the ultra-violet (UV) wavelength region due to surface reflection, scattering, and thermalization losses, which limit conversion efficiency. These losses are mostly caused by the energy difference between the incident UV photons (>3.2 eV) and bandgap of PV cells (1.0-1.6 eV).^{[10]} If these photons are not surface-reflected, their excess energy will be adversely dissipated in cells as heat via the nonradiative relaxation of the photoexcited electron-hole pairs leading to further limitations and faster degradation of PV cells. One of the most promising approaches to overcome these limitations is to implement the surfaces of PV devices with an energy-down-shift quantum-dot (EDS-QD) layer. The function of this EDS-QD layer is to harvest the wasted incident UV photons and re-emit them at a longer wavelength that can be absorbed by PV cells more efficiently to enhance their overall efficiency and performance.^{[11 ]} Moreover, EDS-QDs have been well demonstrated as an effective layer that boosts the energy density then reduces the usage area and number of PV cells, and consequently reduce the cost of PV electricity generation.^{[12]} For the abovementioned reasons, the concept of the EDS-QD layer was proposed for solar energy conversion for both increasing the efficiency and lessening the cost.

Motivated by these purposes, and attracted by their excellent optical properties, Cd-based core/shell QDs, such as CdSe/CdS,^{[11c, 13]} CdSe/CdZnS,^{[14]} CdSe/ZnS,^{[15]} and Cd_{0.5}Zn_{0.5}S/ZnS^{[11b, 16]} QDs have been used recently as EDS layers. However, the relying on the Cd-based QDs in commercial solar cells has been limited due to two main reasons; the toxicity of Cd metal ions^{[17]} and the self-reabsorption losses within their QDs.^{[11a ]} For the latter, Mn-doped Cd_{0.5}Zn_{0.5}S/ZnS QDs have been introduced more recently^{[11a, 12a]} as an excellent EDS-QD layer having free-self-reabsorption with large Stokes shift, yet with environmentally hazardous Cd material. The European Union's Restriction of Hazardous Substances Directive (RoHS) restricts the use of certain hazardous substances, including heavy metals such as Cd, Pb, and Hg, in electrical and electronic equipment; a few exemptions is valid for a fixed-term until a suitable alternative of free-heavy-metals is developed.^{[18]} As a result, the quest for nontoxic high photoluminescence-quantum yield (PLQY) and the zero-self-reabsorption EDS-QD layer is a priority for their commercial applications.

Alternatively, chalcogenide CIGS is one of the most promising semiconductor materials for EDS-QD layers due to its beneficial properties of large absorption coefficient (10⁵ cm⁻¹),^{[19]} eco-friendly nature,^{[18, 20]} long-term stability,^{[21]} and direct bandgap with facile and wide tunability.^{[22]} It is well-known in industrial field that Ga, along with its alloys, is nontoxic and environmentally friendly metal, and therefore has been used as an alternative to Cd and Hg in various applications.^{[23]} In addition to these excellent characteristics, CIGS in its colloidal QD form can work as an effective energy-down converter to render efficient PL peaking at a tunable wavelength ranging from blue to near-infrared by controlling QD size, growth time, and temperature or Cu:In:Ga and Se:S stoichiometries.^{[24]} Accordingly, CIGS QDs have been successfully used as EDS-QD emitters in light-emitting diodes (LED)^{[24c, 25]} and bio-imaging probes.^{[26]} The passivation of CIGS QDs with inorganic materials, such as ZnS, could significantly enhance their PLQY. Among the family of CIGS/ZnS QDs, CuGaS₂/ZnS QDs possess a higher optical bandgap (˜3.1 eV) with large Stokes shift.^{[27]} Both the high optical bandgap and large Stokes shift are of functional importance for EDS-QD application to facilitate the absorption of UV light to be consequently re-emitted at longer wavelengths to hinder the phenomenon of self-reabsorption. Moreover, such visible light is emitted at the desired wide wavelengths with high PLQY (>70%),^{[27-28]} suggesting that CuGaS₂/ZnS QDs are promising as an EDS-QD layer to replace Cd-based QDs in prospective commercial PV applications. Indeed, lower bandgap CuInS₂/CdS and CuInSeₓS₂₋ₓ/ZnS QDs incorporated in poly(lauryl methacrylate) have been reported recently as luminescent solar concentrators (LSC) for Si-PV cells.^{[29]} However, the low power conversion efficiency (PCE) (2-7%) of LSC-Si PV Cells limits their commercialization. In addition, the EQE of commercial crystalline silicon (c-Si) PV cells is peaked at the visible wavelength region (520-700 nm) while the EQE of LSC-Si PVs is peaked at the infrared wavelength region (800-1000 nm). Therefore, higher bandgap QDs such as CuGaS₂/ZnS QDs having PL peaked at the range of 520-700 nm are the choice of most suitable nontoxic EDS-QDs for the conventional c-Si PV cells which dominate >90% of the entire global PV market.^{[18, 30]}

It will be fully appreciated from the foregoing that a necessity is for making nontoxic core/shell QDs having free-self-reabsorption losses and large Stokes shift with a high PLQY working as EDS-QDs layer for solar cells. To reduce the total production costs, core/shell QDs synthesis should be performed through cost-effective, simple, and high-throughput methods, with minimal waste of materials. Furthermore, the prepared EDS-QDs layer should enhance effectively the operating characteristics of photovoltaics with high stability under normal conditions after when deposited on the front side of photovoltaics.

The following references are referred to in the detailed description and are not necessarily material to the examination of this patent application:

[1] a) M. A. Green, Y. Hishikawa, W. Warta, E. D. Dunlop, D. H. Levi, J. Hohl-Ebinger, A. W. H. Ho-Baillie, Prog. Photovolt.: Res. Appl. 2017, 25, 668; b) Y. Wang, S. Bai, L. Cheng, N. Wang, J. Wang, F. Gao, W. Huang, Adv. Mater. 2016, 28, 4532; c) X. Zhang, Y. Xu, F. Giordano, M. Schreier, N. Pellet, Y. Hu, C. Yi, N. Robertson, J. Hua, S. M. Zakeeruddin, H. Tian, M. Grätzel, J. Am. Chem. Soc. 2016, 138, 10742; d) C. Battaglia, A. Cuevas, S. De Wolf, Energy Environ. Sci. 2016, 9, 1552; e) Y. Cao, Y. Saygili, A. Ummadisingu, J. Teuscher, J. Luo, N. Pellet, F. Giordano, S. M. Zakeeruddin, J. E. Moser, M. Freitag, A. Hagfeldt, M. Grätzel, Nature Commun. 2017, 8, 15390.

[2] J. Werner, C.-H. Weng, A. Walter, L. Fesquet, J. P. Seif, S. De Wolf, B. Niesen, C. Ballif, J. Phys. Chem. Lett. 2016, 7, 161.

[3] A. R. Uhl, J. K. Katahara, H. W. Hillhouse, Energy Environ. Sci. 2016, 9, 130.

[4] Z. Li, J. C. W. Ho, K. K. Lee, X. Zeng, T. Zhang, L. H. Wong, Y. M. Lam, RSC Adv. 2014, 4, 26888.

[5] S. Oh, D. H. Jun, K. W. Shin, I. Choi, S. H. Jung, J. Choi, W. Park, Y. Park, E. Yoon, IEEE J. Photovolt. 2016, 6, 1031.

[6] J. D. Poplawsky, W. Guo, N. Paudel, A. Ng, K. More, D. Leonard, Y. Yan, Nature Commun. 2016, 7, 12537.

[7] M. B. Qadir, Y. Li, I. A. Sahito, A. A. Arbab, K. C. Sun, N. Mengal, A. A. Memon, S. H. Jeong, Small 2016, 12, 4508.

[8] a) W. Liao, D. Zhao, Y. Yu, N. Shrestha, K. Ghimire, C. R. Grice, C. Wang, Y. Xiao, A. J. Cimaroli, R. J. Ellingson, N. J. Podraza, K. Zhu, R.-G. Xiong, Y. Yan, J. Am. Chem. Soc. 2016, 138, 12360; b) L. Jiang, W. Chen, J. Zheng, L. Zhu, L. e. Mo, Z. Li, L. Hu, T. Hayat, A. Alsaedi, C. Zhang, S. Dai, ACS Appl. Mater. Interfaces 2017, 9, 26958.

[9] J. Lee, D. H. Sin, B. Moon, J. Shin, H. G. Kim, M. Kim, K. Cho, Energy Environ. Sci. 2017, 10, 247.

[10] a) B. McKenna, R. C. Evans, Adv. Mater. 2017, 29, 1606491; b) X. Huang, S. Han, W. Huang, X. Liu, Chem. Soc. Rev. 2013, 42, 173.

[11] a) M. Jalalah, Y.-H. Ko, F. A. Harraz, M. S. Al-Assiri, J.-G. Park, Nano Energy 2017, 33, 257; b) S.-W. Baek, J.-H. Shim, Y.-H. Ko, J.-S. Park, G.-S. Lee, M. Jalalah, M. S. Al-Assiri, J.-G. Park, J. Mater. Chem. A 2015, 3, 481; c) R. Wang, Y. Shang, P. Kanjanaboos, W. Zhou, Z. Ning, E. H. Sargent, Energy Environ. Sci. 2016, 9, 1130.

[12] a) I. Levchuk, C. Wurth, F. Krause, A. Osvet, M. Batentschuk, U. Resch-Genger, C. Kolbeck, P. Herre, H. P. Steinruck, W. Peukert, C. J. Brabec, Energy Environ. Sci. 2016, 9, 1083; b) N. S. Lewis, Chem. Rev. 2015, 115, 12631.

[13] S. Kalytchuk, S. Gupta, O. Zhovtiuk, A. Vaneski, S. V. Kershaw, H. Fu, Z. Fan, E. C. H. Kwok, C.-F. Wang, W. Y. Teoh, A. L. Rogach, J. Phys. Chem. C 2014, 118, 16393.

[14] H.-J. Jeong, Y.-C. Kim, S. K. Lee, Y. Jeong, J.-W. Song, J.-H. Yun, J.-H. Jang, ACS Appl. Mater. Interfaces 2017, 9, 25404.

[15] S. W. Baek, J. H. Shim, H. M. Seung, G. S. Lee, J. P. Hong, K. S. Lee, J. G. Park, Nanoscale 2014, 6, 12524.

[16] S. W. Baek, J. H. Shim, J. G. Park, Phys. Chem. Chem. Phys. 2014, 16, 18205.

[17] a) A. C. Berends, F. T. Rabouw, F. C. M. Spoor, E. Bladt, F. C. Grozema, A. J. Houtepen, L. D. A. Siebbeles, C. de Mello Donegá, J. Phys. Chem. Lett. 2016, 7, 3503; b) G. Xu, G. Lin, S. Lin, N. Wu, Y. Deng, G. Feng, Q. Chen, J. Qu, D. Chen, S. Chen, H. Niu, S. Mei, K.-T. Yong, X. Wang, Sci. Rep. 2016, 6, 37677.

[18] M. V. Kovalenko, Nature Nanotech. 2015, 10, 994.

[19] M. A. Hossain, M. Wang, K.-L. Choy, ACS Appl. Mater. Interfaces 2015, 7, 22497.

[20] a) S.-C. Chen, Y.-J. Chen, W. T. Chen, Y.-T. Yen, T. S. Kao, T.-Y. Chuang, Y.-K. Liao, K.-H. Wu, A. Yabushita, T.-P. Hsieh, M. D. B. Charlton, D. P. Tsai, H.-C. Kuo, Y.-L. Chueh, ACS Nano 2014, 8, 9341; b) Y. Oh, K. Woo, D. Lee, H. Lee, K. Kim, I. Kim, Z. Zhong, S. Jeong, J. Moon, ACS Appl. Mater. Interfaces 2014, 6, 17740.

[21] a) J. A. d. Cueto, S. Rummel, B. Kroposki, C. Osterwald, A. Anderberg, presented at

Proc. 33rd IEEE Photovoltaic Spec. Conf., 11-16 May 2008; b) D. I. Kim, S. W. Park, S. R. Park, J. Y. Baek, T. y. Yun, H. J. Han, C. W. Jeon, presented at 39th IEEE Photovoltaic Spec. Conf., 16-21 June 2013.

[22] M. R. Golobostanfard, H. Abdizadeh, RSC Adv. 2016, 6, 11903.

[23] a) L. T. Taylor, J. Rancourt, C. V. Perry, US Patent005478978, 1995; b) G. Speckbrock, S. Kamitz, M. Alt, H. Schmitt, US Patent 005800060, 1998; c) L. S. Schlesinger, B. E. Britigan, US Patent006203822, 2001; d) M. Knoblauch, US Patent006063629, 2000; e) T. Zhang, Y. Yang, D. Liu, S. C. Tse, W. Cao, Z. Feng, S. Chen, L. Qian, Energy Environ. Sci. 2016, 9, 3674; f) R. C. Ordonez, C. K. Hayashi, C. M. Tones, J. L. Melcher, N. Kamin, G. Severa, D. Garmire, Sci. Rep. 2017, 7, 10171; g) N. Lazarus, S. S. Bedair, I. M. Kierzewski, ACS Appl. Mater. Interfaces 2017, 9, 1178; h) H. McDaniel, A. Y. Koposov, S. Draguta, N. S. Makarov, J. M. Pietryga, V. I. Klimov, J. Phys. Chem. C 2014, 118, 16987.

[24] a) P.-H. Chuang, C. C. Lin, R.-S. Liu, ACS Appl. Mater. Interfaces 2014, 6, 15379; b) S. Liu, X. Su, RSC Adv. 2014, 4, 43415; c) D.-Y. Jo, D. Kim, J.-H. Kim, H. Chae, H. J. Seo, Y. R. Do, H. Yang, ACS Appl. Mater. Interfaces 2016, 8, 12291.

[24] a) Z. Bai, W. Ji, D. Han, L. Chen, B. Chen, H. Shen, B. Zou, H. Zhong, Chem. Mater. 2016, 28, 1085; b) J.-H. Kim, H. Yang, Chem. Mater. 2016, 28, 6329; c) K. Gugula, L. Stegemann, P. J. Cywinski, C. A. Strassert, M. Bredol, RSC Adv. 2016, 6, 10086.

[24] a) M. G. Panthani, T. A. Khan, D. K. Reid, D. J. Hellebusch, M. R. Rasch, J. A. Maynard, B. A. Korgel, Nano Lett. 2013, 13, 4294; b) T. Pons, E. Pic, N. Lequeux, E. Cassette, L. Bezdetnaya, F. Guillemin, F. Marchal, B. Dubertret, ACS Nano 2010, 4, 2531; c) D. Deng, Y. Chen, J. Cao, J. Tian, Z. Qian, S. Achilefu, Y. Gu, Chem. Mater. 2012, 24, 3029.

[24] D.-Y. Jo, H. Yang, Chem. Commun. 2016, 52, 709.

[24] J.-H. Kim, B.-Y. Kim, E.-P. Jang, C.-Y. Han, J.-H. Jo, Y. R. Do, H. Yang, J. Mater. Chem. C 2017, 5, 6755.

[24] a) R. Sumner, S. Eiselt, T. B. Kilburn, C. Erickson, B. Carlson, D. R. Gamelin, S.

McDowall, D. L. Patrick, J. Phys. Chem. C 2017, 121, 3252; b) F. Meinardi, H. McDaniel, F. Carulli, A. Colombo, K. A. Velizhanin, N. S. Makarov, R. Simonutti, V. I. Klimov, S. Brovelli, Nature Nanotech. 2015, 10, 878.

A. Reinders, P. Verlinden, W. v. Sark, A. Freundlich, Photovoltaic Solar Energy: From Fundamentals to Applications, John Wiley & Sons, Chichester, West Sussex, 2017.

[24] a) D. Tiwari, T. Koehler, X. Lin, A. Sarua, R. Harniman, L. Wang, R. Klenk, D. J. Fermin, ACS Appl. Mater. Interfaces 2017, 9, 2301; b) M. Jalalah, M. Faisal, H. Bouzid, A. A. Ismail, S. A. Al-Sayari, Mater. Res. Bull. 2013, 48, 3351.

### SUMMARY OF THE INVENTION

Provided herein are eco-friendly CuGaS₂/ZnS QDs synthesized on an industrially gram-scale as a replacement to Cd-based QDs EDS layer in PV applications. These QDs exhibit a typical EDS properties that absorb only UV light and emit a wide range of visible light ranging from blue to red. Due to the large Stokes shift of the CuGaS₂/ZnS QDs that can be achieved by tuning their size, optical bandgap and the thickness of an inorganic ZnS shell, they show significant free-self-reabsorption losses. In addition, an extremely high PLQY was achieved through controlling the core growth conditions (temperature and time) and the thickness of the ZnS shell. To the knowledge of the inventors, this is the first study to demonstrate the free-self-reabsorption losses of high PLQY CuGaS₂/ZnS QDs prepared on an industrially gram-scale. Based on the excellent optical properties of CuGaS₂/ZnS QDs, the Cd-free EDS-QD layer was systematically investigated for PV cell application. Through straightforward deposition of these EDS-QDs on the front surface of a monocrystalline p-type silicon (mc-p-Si) solar cell; the short-circuit current density (J_{SC}) and PCE noticeably enhanced. Furthermore, the significant improvements observed in the EQE and surface reflectance (SR) in the UV region by these functional Cd-free EDS-QDs clearly reflect the enhancements in the PV performance. It is important to clarify that the application of the EDS-CuGaS ₂/ZnS QD layer is not limited to Si-based solar cells, but as a proof of concept, it can be used for any type of PV cells having reduction in the UV wavelength region of the EQE spectra and its EQE-peak is centered at the visible region likely between 500 and 600 nm. Tuning the peak is possible as there is still room for further synthetic optimization due to the rich optical properties of CuGaS₂/ZnS QDs.

For studying the industrial applicability and economic feasibility of this approach, we carefully followed the bill of material-system (BoM-S) analysis method by using the commercial Si PV module Q.PLUS L-G4.1 335 from Hanwha Q Cells with a PCE value mostly similar to our experimental solar cells. Furthermore, the up-scaling production of the Cd-free QDs was carried out for the first time in a facile one-pot core/shell synthesis using an industrial-sized 2000-mL three-neck flask with very good reproducibility.

In summary, the invention is a method of making a new eco-friendly energy-down-shift (EDS)-QD layer by using Cd-free CuGaS₂/ZnS core/shell QDs for photovoltaic applications. The successful up-scaling of these QDs via a facile one-pot core/shell synthesis using an industrial-sized 2000-mL three-neck flask, impressive high PLQY reaching 76% and very good reproducibility make them a promising alternative to Cd-based QDs for a broad range of eco-friendly applications such as solar cells and white-LEDs. Our CuGaS₂/ZnS QDs showed strong free-self-reabsorption losses due to their large Stokes shift (>190 nm), in which they exhibited a typical EDS that absorbs only UV light and re-emits a wide range of longer-wavelength visible light. The straightforward application of these QDs on the front surface of a monocrystalline p-type silicon (mc-p-Si) solar cell significantly enhanced the short-circuit current density (J_{sc}) and power conversion efficiency (PCE) by ˜4.20 and ˜4.11%, respectively. The significant improvements in the external quantum efficiency (EQE) increased by ˜35.7% and the surface reflectance decreased by ˜14.1% in the UV region (300-450 nm) represent the EDS mechanism of our QDs and clearly reflects the enhancements in J_{SC} and PCE. Accordingly, a 2.62% reduction in the overall production cost of mc-p-Si solar cell modules, calculated using a bill of material-system (BoM-S) analysis, was achieved with this effective eco-friendly EDS-QD layer. Such promising enhancements in PV characteristics together with the simple, cost-effective, and scalable preparation of the EDS-QD layer as well as the rich optical properties of our free-self-reabsorption CuGaS₂/ZnS QDs pave the way for applying them into different types of PV cells that have low EQE in the UV region, such as GIGS, CZTS, GaAs, CdTe, DSSC, perovskite, and organic solar cells. Future work on these Cd-free CuGaS₂/ZnS QDs is currently directed toward further improvement of their PLQY and more uniform coating process of EDS-QD layer correlated with thickness optimization for less costly and more efficient commercial solar cells.

### BRIEF DESCRIPTION OF THE DRAWINGS

FIG. 1 is a schematic illustration of (a) energy losses in typical monocrystalline p-type silicon solar cells having no energy-down-shift quantum-dot. layer; and (b) energy-down-shift quantum-dot layer implemented on textured pyramid-like surface of monocrystalline p-type silicon solar cell.

FIG. 2 is a schematic illustration of the one-pot core/shell synthesis methods of CuGaS₂/ZnS QDs.

FIG. 3 is the structural and morphological characterizations of as-synthesized CuGaS₂/ZnS QDs. (a) X-ray diffraction (XRD) pattern (standard JCPDS files for zinc blende ZnS and Chalcopyrite CuGaS₂ are shown on top and bottom, respectively) and corresponding selected area electron diffraction (SAED) pattern (inserted image). (b) High-resolution transmission electron microscopy (HRTEM) image with a scale bar of 5 nm, 2 nm (inset, upper right), and size distribution (inset, upper left).

FIG. 4 is the energy-down-shift mechanism of CuGaS₂/ZnS QDs. (a) Absorption and photoluminescence spectra of CuGaS₂/ZnS QDs, CIExy 1931 (inset, under PL spectra), and emitting light photography under UV-lamp of 365 nm (inset, right). (b) Energy-bandgap-alignment diagram of CuGaS₂/ZnS QDs.

FIG. 5 is the photovoltaic performance of Si solar cells implemented with energy-down-shift layer of CuGaS₂/ZnS QDs. (a) Short-circuit current density (J_{SC}) and open-circuit voltage (V_{OC}) curves. (b) Fill factor (FF) and power conversion efficiency (PCE).

FIG. 6 shows (a) the cross-sectional TEM image of EDS-QD layer implemented on mc-p-Si solar cell (scale bar=100 nm); and (b) the zoomed-in HRTEM image of EDS-QD layer in scale bar of 5 nm.

FIG. 7 is the short-circuit current density vs. open-circuit voltage (J-V) characteristics comparison between the solar cell sample coated with the optimal QD concentration (0.4 wt %) and bare sample.

FIG. 8 shows (a) the external quantum efficiency (EQE) of Si solar cells implemented with energy-down-shift layer of CuGaS₂/ZnS QDs, and surface reflectance (inset) of 0.4 wt % QD concentration sample; and (b) the change ratio in the integrated UV region (300-450 nm) of EQE as a function of QD concentrations (0, 0.1, 0.2, 0.3, 0.4, 0.5 and 0.7 wt %).

FIG. 9 is the surface reflectance (SR) of Si solar cells implemented with energy-down-shift (EDS) layer of CuGaS₂/ZnS QDs. (a) SR spectra in wavelength-range of 300-1100 nm and (b) integrated area of SR over a range of 300-450 nm (UV light) and 450-800 nm (visible light) as a function of QD-wt % concentrations.

FIG. 10 is the gram-scale synthesis of CuGaS₂/ZnS QDs. (a) 11 gram of purified QD powder on a digital scale under UV-365 nm lamp. (b) Absorption and photoluminescence (PL) of QDs in chloroform as shown in the inset image of vial under UV-365 nm lamp. PL was excited by 325 nm-laser source.

### DETAILED DESCRIPTION

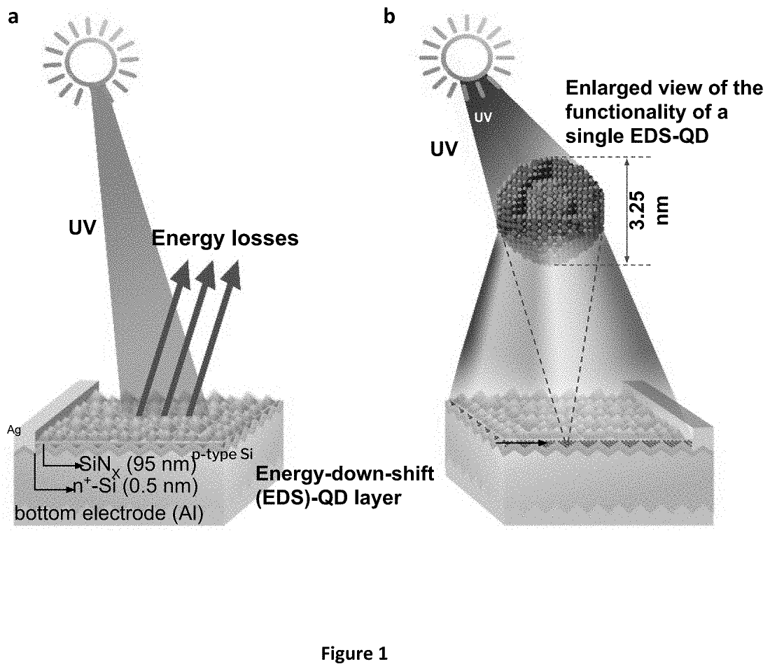

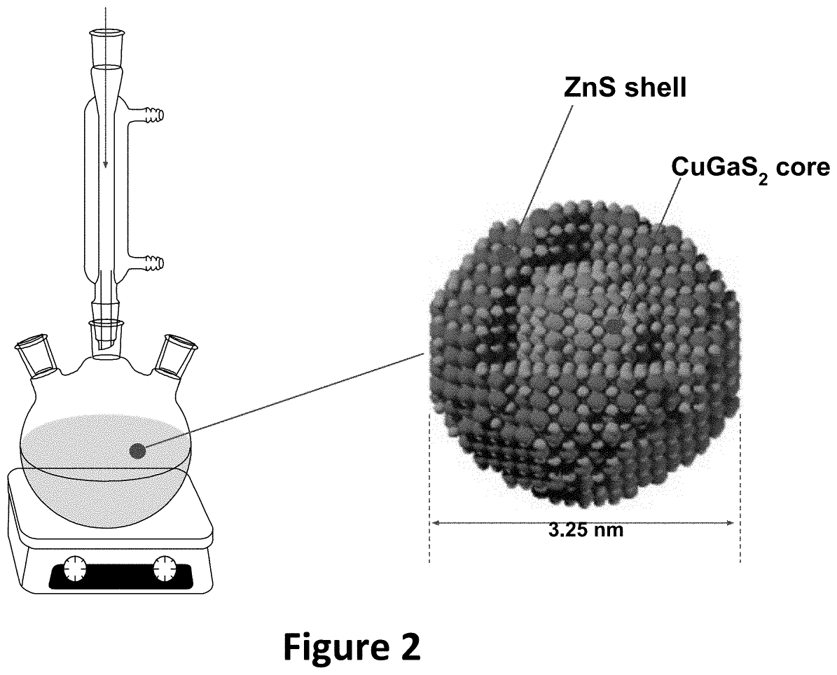

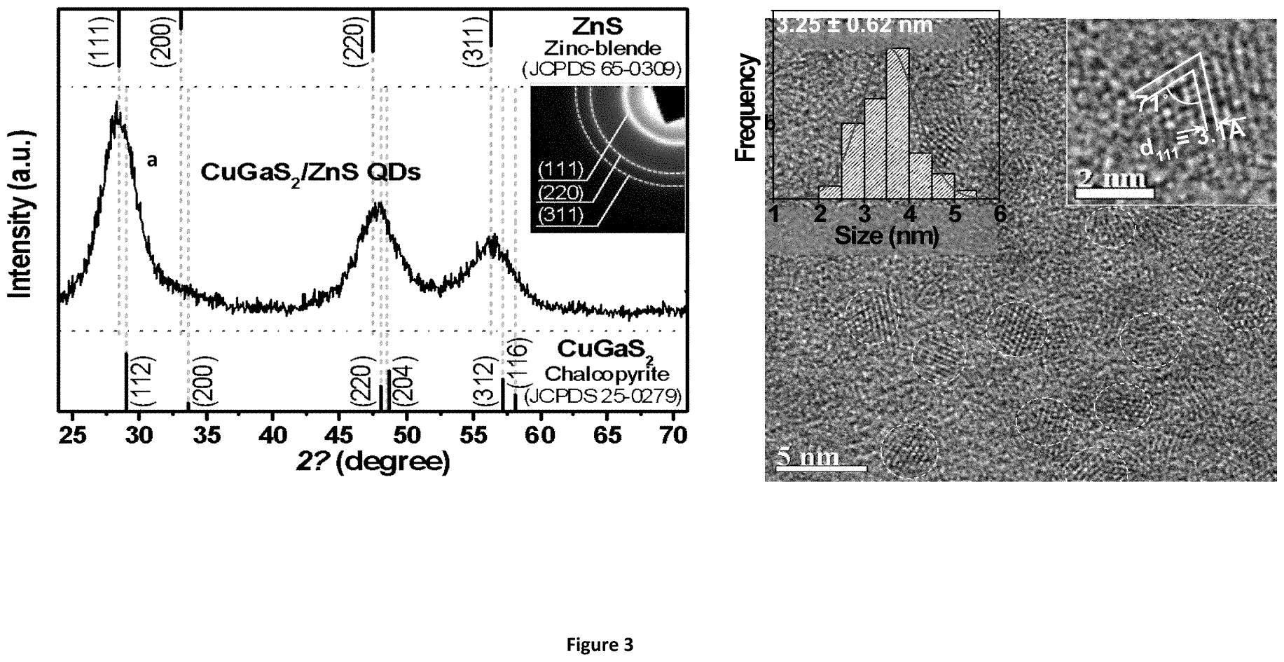

To avoid excessive energy losses of UV photons by the surface scattering and reflection in solar cells (FIG. 1), an eco-friendly EDS-QD layer has been provided to be employed on the surface of the fabricated mc-p-Si solar cells as an efficient UV-harvesting down-converter to the whole range of visible light (FIG. 1). The Cd-free CuGaS₂/ZnS QDs were prepared via the conventional wet colloidal synthesis using a simple one-pot core/shell method at low growth temperature ranging from 180° C. for the inner core to 250° C. for the outer shell under N₂ atmosphere (FIG. 2). To investigate the structural and morphological characterizations of as-synthesized CuGaS₂/ZnS QDs, X-ray diffraction (XRD), selected area electron diffraction (SAED), and transmission electron microscopy (TEM) were carried out (FIG. 3). In the wide-angle diffraction region (FIG. 3a), the XRD pattern revealed that the QDs possess a single-crystal chalcopyrite structure (referred to as the tetragonal phase). The characteristic (112), (220)/(204), and (116)/(312) planes of the chalcopyrite structure were observed with a slight shift toward lower 2θ angles to be centered at 28.4, 47.9, and 56.5°, respectively, approaching those 2θ angles of the (111), (220), and (311) planes of the zinc blende ZnS structure (referred to as the cubic phase). This shift is highly characteristic of the successful formation of the outer ZnS shell. The SAED image (the inset of FIG. 3) also confirms the presence of the ZnS shell since the distinct rings clearly originated from (111), (220), and (311). The broad diffractive peaks observed in the XRD pattern are indicative of the small particle size of the as-synthesized QDs. The average crystallite size was estimated from the dominant (111) peak using Scherrer's formula to be ˜3.04 nm. It is apparent from the TEM micrograph (FIG. 3) that the well-dispersed and crystallized QDs have a spherical-like shape with a fairly uniform size of about 3.25±0.62 nm (the left inset of FIG. 3), which is in reasonable agreement with the estimated XRD result. The right inset high-resolution TEM (HRTEM) image (scale bar =2 nm) shows that the lattice interplanar spacing of an individual QD is ˜3.1 Å, which is slightly higher than the d₁₁₂-spacing of CuGsS₂ (3.0655 Å) but much closer to the d₁₁₁-spacing of ZnS (3.1261 Å) with an interplanar angle of ˜71° providing further evidence of the core/shell structure (the right inset of FIG. 3).

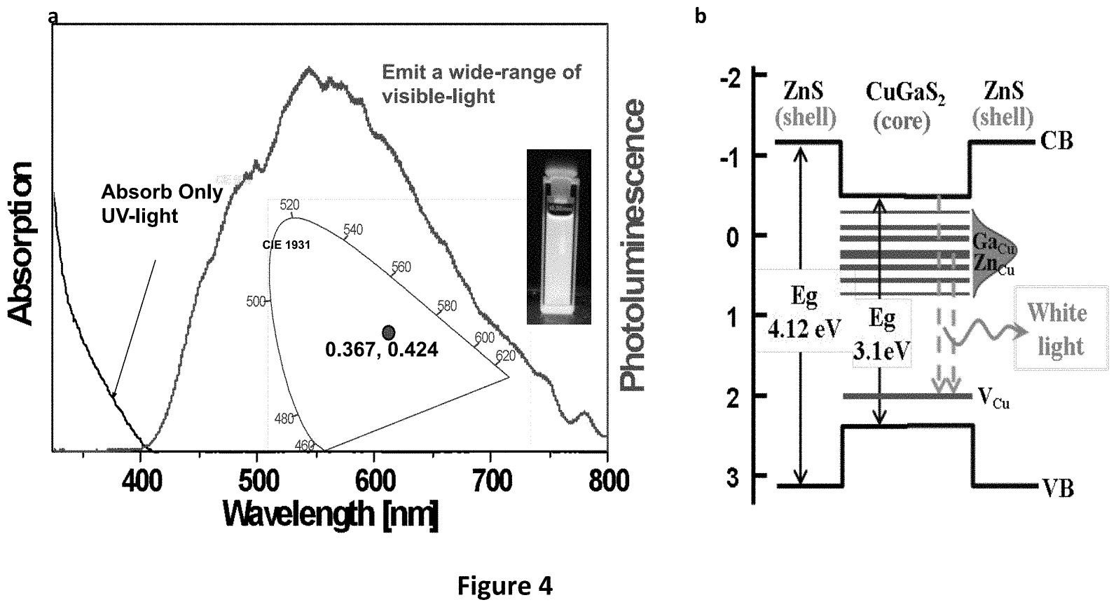

The optical properties of the as-prepared CuGaS₂/ZnS QDs were systematically characterized and optimized as EDS-QDs to harvest the wasted UV light from the sun and re-emit it as visible light for solar cell applications. The absorption and PL spectra of the CuGaS₂/ZnS QDs, dispersed in chloroform, show that they absorb only UV light (<407 nm) and emit a wide range of visible light (400-800 nm) peaked at 544 nm (FIG. 4). The International Commission Illumination (CIE) color coordinates and emitting light photography of these QDs, excited by 325 and 365 nm, respectively, reveal that the QDs can emit in a bright saturated white color making these QDs also very attractive for optoelectronic applications such as LEDs and displays (the insets of FIG. 4). The successful growth of the inorganic ZnS shell was essential to passivate the outer surface of the CuGaS₂ core to remove the surface defects (such as surface imperfections, trapping states, and dangling bonds); therefore, enhancing the optical properties of QDs, especially for the exciton radiative recombination. In addition, this inorganic shell acts as an effective energy barrier to confine the photo-excited excitons in the core due to type-I band offset alignment between the core and the shell; then limit the sensitivity of the core to lower-energy photons, as shown in the energy bandgap diagram (FIG. 4). The optical bandgap of the QDs was estimated from the direct-bandgap absorption using Tauc equation of the transformed Kubelka-Munk function.^{[31]} It is obvious that the ZnS shell (bandgap of ˜4.12 eV) has higher conduction band (CB) and lower valence band (VB) than that of the CuGaS₂ core (bandgap of ˜3.1 eV); therefore, the shell layer enhances PLQY to ˜76%. More importantly, coherently with the above-mentioned absorption and PL properties, these QDs exhibit free-self-reabsorption losses due to the large Stokes shift (>190 nm). These results make the as-prepared QDs comparable to the recently reported Mn-doped Cd_{0.5}Zn_{0.5}S/ZnS QDs that had the phenomenon of zero self-reabsorption used for enhancing the efficiency of Si solar cells.^{[11a, 12a]} Accordingly, these CuGaS₂/ZnS QDs can function as an effective EDS layer for solar cells.

To demonstrate the feasible application of these Cd-free CuGaS₂/ZnS QDs and consequently the effect of this EDS-QD layer on the PV performance of solar cells, we first optimized the concentration of the EDS-QD layer to increase the absorption of solar cells. Six different concentrations of the optimized EDS-QDs (0.1, 0.2, 0.3, 0.4, 0.5, and 0.7 wt %) in chloroform were prepared to be coated on Si solar cells. The concentration of EDS-QDs has a considerable effect on the efficiency of solar cells, according to previous studies.^{[11a, 12a]} These six prepared QD solutions were deposited subsequently on the front surface of textured mc-p-Si solar cells, fabricated with a SiNₓ anti-reflective surface, using the doctor blade casting technique.

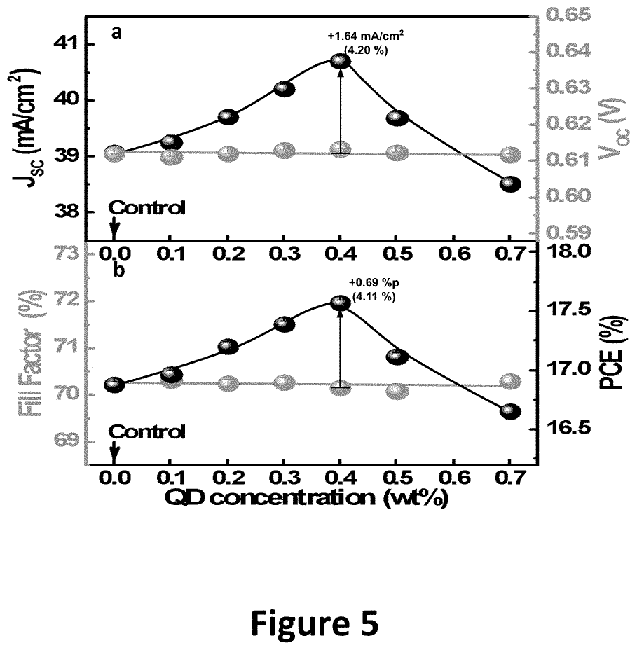

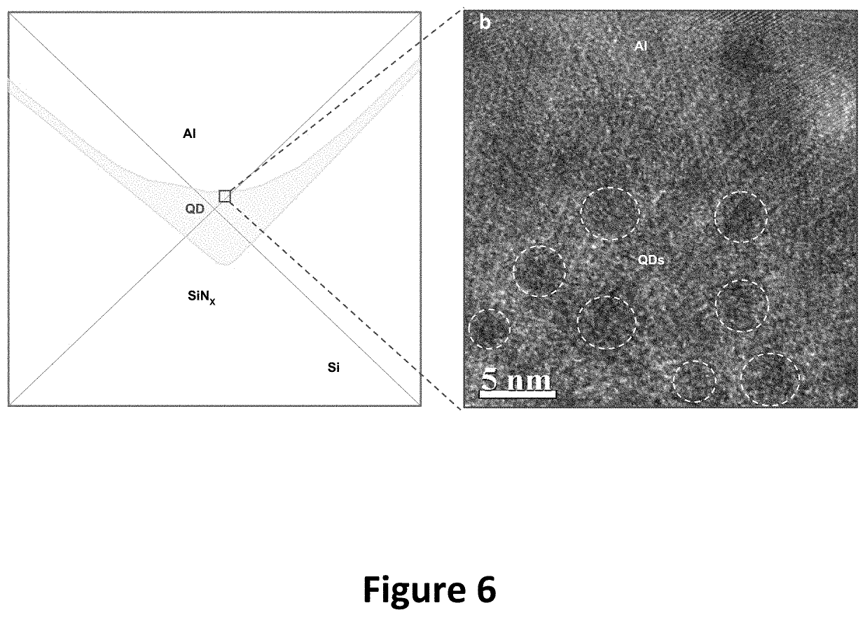

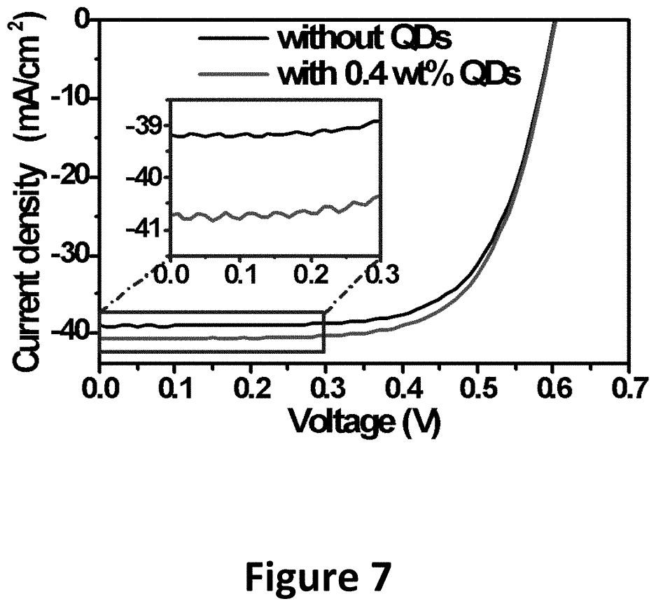

FIG. 5 illustrates the PV performance characteristics, open-circuit voltage (V_{OC}), fill factor (FF), short-circuit current density (J_{SC}), and PCE of the mc-p-Si solar cells implemented with eco-friendly EDS-QDs as a function of QD concentration. The current density-voltage (J-V) measurements were carried out with the AM1.5G solar simulator under standard test conditions at room temperature and irradiance of 100 mW/cm². The J-V measurements were carried out for all solar cell samples before applying the EDS-QD layer to simplify the performance comparison. It was found that the solar cells coated with the EDS-QD layer with 0.4 wt % QD concentration had the highest J_{SC}. Specifically, the J_{SC} increased gradually from 39.07 to 40.71 mA/cm² with the QD concentration to peak at 0.4 wt % then decreased rapidly to reach 38.51 mA/cm² at 0.7 wt %. This optimal 0.4 wt % concentration, which formed an EDS-QD layer thickness of ˜70 nm of well-dispersed QDs, deposited in a concaved structure at the bottom to decrease gradually to ˜5 nm at the sides of pyramids on the surface of mc-p-Si solar cell (FIG. 6). This led to enhance the J_{SC} by +4.20% compared to the bare solar cell (FIG. 5). The PCE results showed, interestingly, a very similar tendency to that of J_{SC}. In particular, the PCE progressively increased from 16.88 to 17.57% with the QD concentration to record a peak at 0.4 wt %, presenting a PCE enhancement of +4.11% (+0.69% p) then negatively decreased with further increase in QD concentration, such as 16.65% at 0.7 wt % (FIG. 5). The increment in PCE of our QDs was exceeding the theoretical limit (0.6% p) which is comparable to those published recently for Mn-doped CdₓZn₁₋ₓS/ZnS QDs (0.5% p).^{[12a]} It should be noted that all solar cell samples coated with QD concentrations lower than ˜0.6 wt % exhibited better PV performance compared to the bare samples. However, a higher wt % causes a dramatic decrease in the performance of solar cells. FIG. 7 shows the J-V characteristics comparison between the solar cell sample coated with the optimal QD concentration (0.4 wt %) and bare sample. In contrast to the QD concentration dependency of Jsc and PCE, the Voc and FF showed almost no response to the wt % concentration of QDs (FIG. 5) indicating that the coating of the EDS-QD layer on the solar cells has almost no effect on V_{OC} and FF but on J_{SC} and PCE. The significant enhancements in J_{SC} and PCE can be primarily explained due to the effective EDS mechanism incorporated with the high PLQY (˜76%) and free-self-reabsorption within the CuGaS₂/ZnS QDs, resulting in an excess energy of visible photons available for solar cells. Therefore, these observations clearly indicate the potential benefits and effectiveness of this EDS-QD layer for the development of eco-friendly solar cell applications.

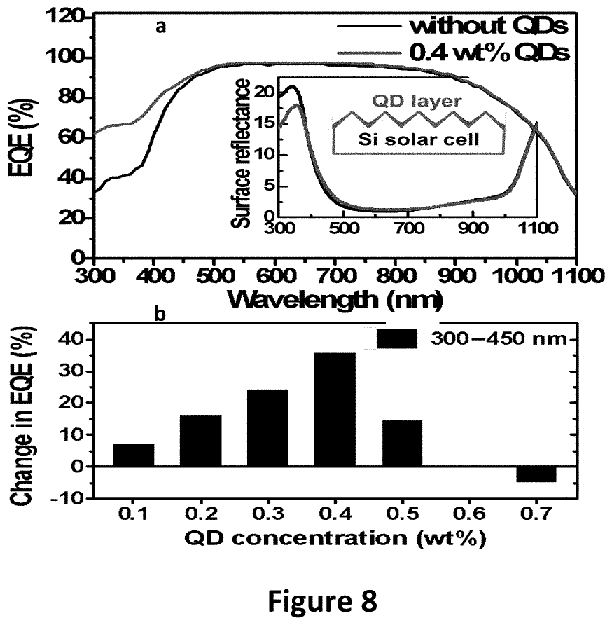

To further understand the significant increase in J_{SC} after the coating of an effective EDS-QD layer and the reason behind the dramatic degradation of performance when the QD concentration exceeds ˜0.6 wt %, all samples were subjected to EQE and SR measurements. The EQE is mainly for investigating the former (the increase in J_{SC}) while the SR for the latter (the degradation of performance). The EQE and SR measurements were taken for the bare mc-p-Si solar-cell samples before adding the EDS-QD layer. These measurements were carried out again after applying the EDS-QD layer. FIG. 8 shows the EQE and SR (inset) results of the optimal concentration (0.4 wt %) presenting the highest J_{SC}. It reveals that the EQE increased by ˜35.7% and, simultaneously, the SR decreased by ˜14.1% in the UV region between 300 and 450 nm after the coating of the functional Cd-free QDs, which reflect the clear presence of the EDS function rule in the QD layer that led to the enhancement in J_{SC}. The corresponding calculations of the change in EQE (AEQE) in percentages (FIG. 8) showed similarity to the tendency of J_{SC}. In particular, AEQE in the UV region ranging from 300 to 450 nm increased gradually from ˜7.3 to ˜35.7% for the QD concentration from 0.1 to 0.4 wt %, respectively, then further concentration led to more reduction in ΔEQE. In general, all QD concentrations, except 0.7 wt %, displayed an increase in the EQE in the UV region with no noticeable degradation in the visible wavelength region (450-800 nm). On the other hand, 0.7 wt % showed a contradictory result in that EQE deceased in both UV and visible regions and negative performance in J-V measurements compared to its reference sample (without QDs). Thus, as a conclusion, the increase in EQE in the UV region verifies the effectiveness of the EDS-CuGaS₂/ZnS QD layer as an energy-down converter that leads to direct enhancement in both J_{SC} and PCE.

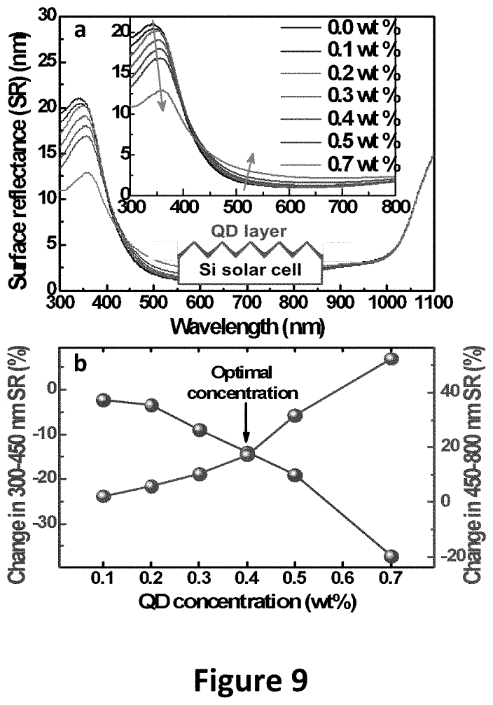

In addition to EQE characterizations, the SR was investigated using UV-visible light spectrometry for further understanding of the underlying mechanism behind the observed tendency in J_{SC}. Previous works on EDS Cd-based QDs for solar cell applications used SR data, along with EQE, to explain the enhancements in solar cell performance as a function of QD concentration or thickness of EDS-QD layer.^{[11a, 11b, 15-16]} FIG. 9 depicts the SR results of the mc-p-Si solar cells implemented with the EDS-QD layer at various QD concentrations, as mentioned above. It was observed that the decrease in SR in the UV region (300-450 nm) with QD concentrations is accompanied by an increase in the visible region (450-800 nm) (FIG. 9). The decrease in the UV region clearly explains the beneficial effect of the EDS-QD layer in harvesting incident UV photons on the surface of solar cells. In other words, the higher the QD concentration, the higher absorption then lower reflectance in the UV region. This enhancement was limited by the accompanying increase in SR in the visible region (450-800 nm) due to the scattering of visible light that increases with QD concentration in the EDS-QD layer. FIG. 9 shows that a lower concentration than 0.4 wt % leads to a higher SR in the UV region while a higher concentration leads to a higher SR in the visible region. Therefore, the QD concentration should be considered carefully for scale-up applications of the EDS-CuGaS₂/ZnS-QD layer on any type of solar cells. The high PLQY, free-reabsorption and nontoxicity features of our CuGaS₂/ZnS QDs indicate that they are promising as a Cd-free EDS-QD layer for clean, eco-friendly, and highly efficient future solar cells.

The EDS-QD layer can be readily implemented to currently used PV modules to enhance their PCE with no costly replacements of the whole modules via a straightforward coating. The successful marketing and industrial applicability of this EDS-QD layer for commercial PV modules depend essentially on their economic feasibility and capability for industrial productivity. To investigate their economic feasibility, we conducted a bill of material-system (BoM-S) analysis^{[12a]} to calculate and examine the BoM-S cost of the Cd-free EDS-QD layer regarding its PV enhancements. We found that the EDS-CuGaS₂/ZnS QD layer with an optimal concentration of 0.4 wt % can effectively reduce the price of the commercial 248.4-watt Q.PLUS L-G4.1 335 mc-Si module by 2.62% due to the enhanced PCE (+4.11%), which facilitates the reduction in the usage area and the number of PV cells.

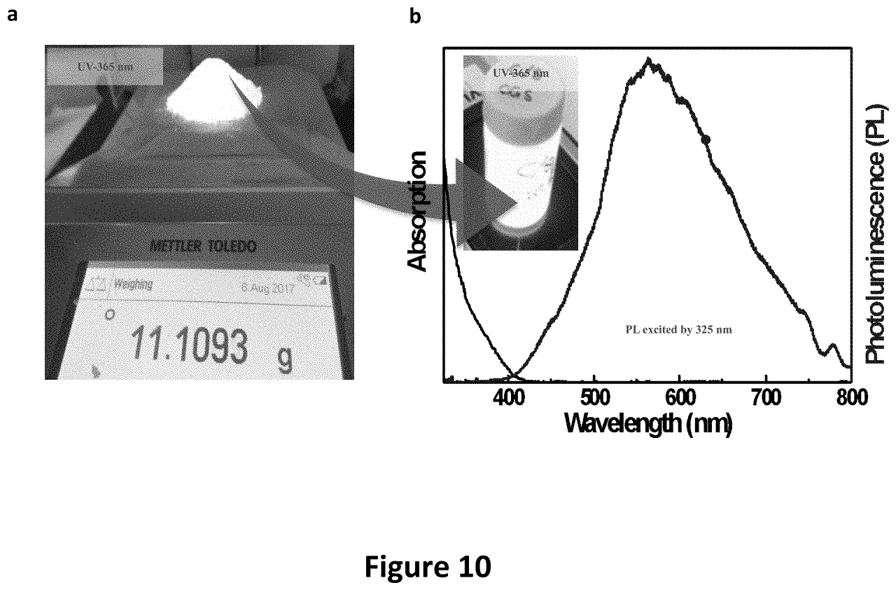

Furthermore, the up-scaling production of Cd-free CuGaS₂/ZnS QDs was carried out for the first time in a facile one-pot core/shell synthesis for industrial producibility. This was achieved using an industrial-sized 2000-mL three-neck flask to produce 11 g of CuGaS₂/ZnS QD powder at high-quality and very good reproducibility (FIG. 10). The optical characterizations of the QD powder dispersed in chloroform show that they have an optical bandgap of ˜3.05 eV and a wide range of PL emission peaked at 465 nm with a high PLQY of 73-76% (FIG. 10). It is important to mention that the purification process is essential for this QDs. The more cycles of purification, the higher PLQY can be achieved. These QDs show high bright white emission when they illuminated by 365 nm light under UV-lamp in both the powder form (FIG. 10) and the solution form (the inset of FIG. 10).

We claim:

1. A monocrystalline p-type silicon solar cell device comprising:
an eco-friendly front layer of CuGaS₂/ZnS core/shell nanocrystals layer, working as typical energy-down-shift layer to absorb only ultraviolet light and emit the whole range of visible light with a high photoluminescence-quantum yield;
wherein the energy-down-shift layer has free-self-reabsorption losses and large Stokes; and
wherein CuGaS₂/ZnS core/shell nanocrystals have been synthesized on an industrially one-pot gram-scale.
the straightforward application of this energy-down-shift layer on the front surface of a monocrystalline p-type silicon solar cell significantly enhanced the short-circuit current density and power conversion efficiency.

2. The CuGaS₂/ZnS core/shell nanocrystals layer of claim 1, wherein the energy-down-shift layer absorbs ultraviolet light of wavelength lower than 407 nm.

3. The CuGaS₂/ZnS core/shell nanocrystals layer of claim 1, wherein the energy-down-shift layer emits the visible light in the wavelength range of 400-800 nm.

4. The CuGaS₂/ZnS core/shell nanocrystals layer of claim 1, wherein the energy-down-shift layer has photoluminescence-quantum yield of ˜76%.

5. The CuGaS₂/ZnS core/shell nanocrystals layer of claim 1, wherein the energy-down-shift layer has a large Stokes shift greater than 190 nm.

6. The monocrystalline p-type silicon solar cell of claim 1, having a current density improved by ˜1.64 mA/cm² (+4.20%).

7. The monocrystalline p-type silicon solar cell of claim 1, having an efficiency improved by ˜4.11%.

8. The monocrystalline p-type silicon solar cell of claim 1, having an external quantum efficiency increased by ˜35.7%.

9. The monocrystalline p-type silicon solar cell of claim 1, having a surface reflectance decreased by ˜14.1% in the UV region of 300-450 nm.

10. A method of synthesizing CuGaS₂/ZnS Nanocrystals on an industrially one-pot gram-scale comprising the steps of:
mixing a first mixture at least gallium iodide, copper iodide, 9-Octadecenylamine, and 1-dodecanethiol and heating to at least 100 degrees Celsius;
injecting sulfur at least 160 degrees Celsius into said first mixture, forming a second mixture with a core of CuGaS₂;
injecting into said second mixture zinc sterate forming an opaque layer creating a third mixture;
depositing said third mixture on a solar cell as the energy-down-shift layer said in claim-1.

11. The method of claim 10, wherein said mixing of said first mixture is carried out at or above 125 degrees Celsius.

12. The method of claim 11, wherein said injecting is at 180 degrees.

13. The method of claim 10, wherein said first mixtur

[symbol]

14. [symbol] e further comprises oleic acid.

15. The method of claim 13, wherein said first mixture further comprises 1-octadecene.

16. The monocrystalline p-type silicon solar cell of claim 1, further comprising a step of preparing said solar cell by immersing a p-type single-crystalline silicon substrate in potassium hydroxide.

17. The method of claim 15, wherein said step of preparing said solar cell further comprises adding phosphoryl chloride to said solar cells forming phosphorous silicate glass.

18. The method of claim 16, wherein an n-type layer is created on said solar cell with an emitter resistance of about 58 ohm per square.

19. The method of claim 10, wherein said depositing comprises depositing CuGaS₂/ZnS nanocrystals solution by weight percentage between 0.3% and 0.5% on the front surface of said solar cell.

20. The method of claim 17, wherein said nanocrystals solution is CuGaS₂/ZnS nanocrystals dispersed in an organic solvent.
